(19) United States
(12) Patent Application Publication
(10) Pub. No.: US 2007/0045040 A1
(43) Pub. Date: Mar. 1, 2007

(54) Speaker assembly for a structural pole and a method for mounting same

(76) Inventor: Ronald Paul Harwood, Farmington Hills, MI (US)

Correspondence Address: BROOKS KUSHMAN P.C., 1000 TOWN CENTER, TWENTY-SECOND FLOOR, SOUTHFIELD, MI, 48075, US

(21) Appl. No.: 11/209,794

(22) Filed: Aug. 23, 2005

(51) Int. Cl. A47B 81/06; H05K 5/00

(52) U.S. Cl. 181/199; 181/148

(57) ABSTRACT

A speaker assembly for a structural pole is provided, as well as a method for attaching a speaker assembly to a structural pole. The speaker assembly is provided with an elongate housing mounted to banner brackets that are affixed to the structural pole. The housing is sized to provide an aesthetic appearance that corresponds to a banner attached to the banner brackets. A speaker, or a plurality of speakers are provided within the housing for transmitting acoustic vibrations to a corresponding environment.

### BACKGROUND OF THE INVENTION

1. Field of the Invention

The invention relates to a speaker assembly, more particularly to a speaker assembly for a structural pole.

2. Background Art

Many outdoor and indoor public environments and thoroughfares utilize speakers, speaker systems or public address systems for amplifying sound and/or sound reproduction. Such areas may include city streets, parks, residential neighborhoods, office buildings, campuses, exterior walkways, shopping malls, casinos, dealerships, sports venues, atriums, amusement parks, wharfs, or the like. These areas typically utilize speakers or speaker systems that are mounted to existing building structures, structural poles, or the like. Much effort is employed in installation of these systems and protecting these systems from vandalism, theft and/or the weather.

The prior art has offered methods and apparatuses for mounting speakers and speaker systems in public areas. The prior art also provides apparatuses for protecting speakers from the elements. The prior art has offered solutions for concealing speaker systems in public areas. Many prior art speaker systems may be costly in light of the advantages provided due to manufacturing costs of various components and complex apparatuses for concealing or protecting the speakers. Further, these prior art speaker systems may detract from the aesthetic appearance of the environment.

Often, a structural pole has a primary feature, such as providing lighting to a thoroughfare. The structural pole may also serve a display purpose, by utilization of a banner or a plurality of banners mounted to the structural pole by banner brackets.

A simplified speaker apparatus and system is needed for use in public environments that incorporates the speaker system into existing or accepted objects within the environment for providing a desired quality in amplitude of sound reproduction, while not upsetting or obfuscating the aesthetic appearance or display of the area.

### SUMMARY OF THE INVENTION

A non-limiting embodiment of the present invention provides a speaker assembly for attachment to a structural pole. A speaker assembly includes an elongate housing having an upper end and a lower end, each adapted to be secured to a banner bracket of a structural pole. The housing provides an aesthetic appearance that corresponds with a banner attached to the banner brackets of the structural pole. At least one speaker is retained within the housing and is oriented to face generally outward from the housing for transmitting acoustic vibrations to a corresponding environment.

Another non-limiting embodiment of the present invention provides a method for mounting a speaker assembly to a structural pole. A speaker assembly is provided having an elongate housing with a speaker disposed therein. The speaker assembly is mounted to banner brackets on a structural pole.

### BRIEF DESCRIPTION OF THE DRAWINGS

FIG. 1 is a front side elevation view of a speaker assembly in accordance with the present invention, illustrated mounted to a structural pole;

FIG. 2 is an enlarged front side elevation view of the speaker assembly of FIG. 1;

FIG. 3 is an enlarged right side elevation view of the speaker assembly of FIG. 1;

FIG. 4 is a front side elevation view of the speaker assembly of FIG. 1, illustrated with a screen removed therefrom;

FIG. 5 is a right side partial section view of the speaker assembly of FIG. 1;

FIG. 6 is an enlarged perspective view of a lower end of the speaker assembly of FIG. 1;

FIG. 7 is a right side partial section view of the speaker assembly of FIG. 1, illustrated with the screen removed therefrom;

FIG. 8 is a back side elevation view of the speaker assembly of FIG. 1;

FIG. 9 is an enlarged perspective view of a port of the speaker assembly of FIG. 1;

FIG. 10 is a top plan view of the speaker assembly and the structural pole of FIG. 1, illustrated with an alternative embodiment light source in accordance with the present invention;

FIG. 11 is a top plan view of the speaker assembly of FIG. 1, illustrated attached to a structural pole by an alternative attachment apparatus in accordance with the present invention;

FIG. 12 is a top plan view of the speaker assembly of FIG. 1, illustrated attached to a structural pole by another alternative attachment apparatus in accordance with the present invention; and

FIG. 13 is a front side elevation view of an alternative embodiment speaker assembly in accordance with the present invention, illustrated attached to a structural pole.

### DESCRIPTION OF EMBODIMENTS OF THE INVENTION

As required, detailed embodiments of the present invention are disclosed herein; however, it is to be understood that the disclosed embodiments are merely exemplary of the invention that may be embodied in various and alternative forms. The figures are not necessarily to scale, some features may be exaggerated or minimized to show details of particular components. Therefore, specific structural and functional details disclosed herein are not to be interpreted as limiting, but merely as a representative basis for the claims and/or as a representative basis for teaching one skilled in the art to variously employ the present invention.

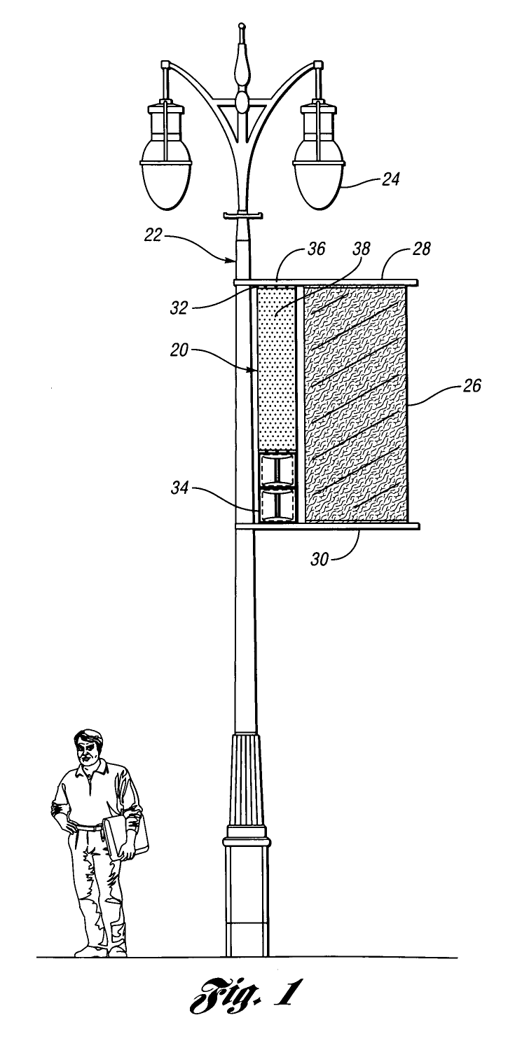

With reference now to FIG. 1, a speaker assembly is illustrated in accordance with the present invention, and referenced generally by numeral 20. The speaker assembly 20 is illustrated attached to a structural pole 22. The structural pole 22, for example, may be a light pole having a light source 24 supported therefrom for illuminating an underlying environment or thoroughfare.

The structural pole 22 is also provided for displaying a banner 26. Accordingly, an upper banner bracket 28 and a lower banner bracket 30 are provided on the structural pole 22 for securing and displaying the banner 26. An upper end 32 of the speaker assembly 20 is attached to the upper banner bracket 28 and a lower end 34 of the speaker assembly 20 is attached to the lower banner bracket 30.

The speaker assembly 20 may be dimensioned to attach to conventional banner brackets 28, 30 and may be sized for placement between the structural pole 22 and the banner 26. The speaker assembly 20 may be sized to provide an aesthetic appearance that corresponds with that of a conventional banner 26. Thus, the speaker assembly 20 and the structural pole 22 blend harmoniously into the environment. Moreover, as speaker assemblies are utilized in places of public congregation, there is a need for blending the aesthetics of structural pole 22, the banner 26 and the speaker assembly 20. Thus, the generally linear or vertical arrangement of the speaker assembly 20 facilitates cooperation of the speaker assembly 20 with commercially available banner mounting equipment such as the upper and lower banner brackets 28, 30. Of course, the invention contemplates that the speaker assembly 20 may include dedicated brackets for supporting both the speaker assembly 20 and the banner 26.

By providing the speaker assembly 20 with dimensions that match conventional or standard banner sizes, existing structural poles having a banner 26 and banner brackets 28, 30 may be retrofitted with a speaker assembly 20.

The invention contemplates that more than one speaker assembly 20 may be provided on the banner brackets 28, 30. Additionally, the present invention contemplates that the speaker assembly 20 may be provided adjacent to the banner 26 as illustrated, or may be provided behind the banner 26. Often, the banner brackets 28, 30 support a pair of banners 26, each facing opposed directions. Thus, the invention contemplates that the speaker assembly 20 may be provided between the pair of banners 26 thereby concealing the speaker assembly 20.

The prior art has provided banners and banner brackets that extend on one lateral side of a structural pole 22, as illustrated in FIG. 1. The prior art has also provided banners 26 and banner brackets 28, 30 that extend laterally from more than one side of a structural pole 22. Thus, the invention contemplates utilization of the speaker assembly 20 on one or more lateral side of the structural pole 22. By utilization of both lateral sides of the structural pole 22, a pair of speaker assemblies 20 may be provided, each facing opposed directions for transmitting acoustical vibrations to both a front side and a rear side of the thoroughfare with respect to the banners 26.

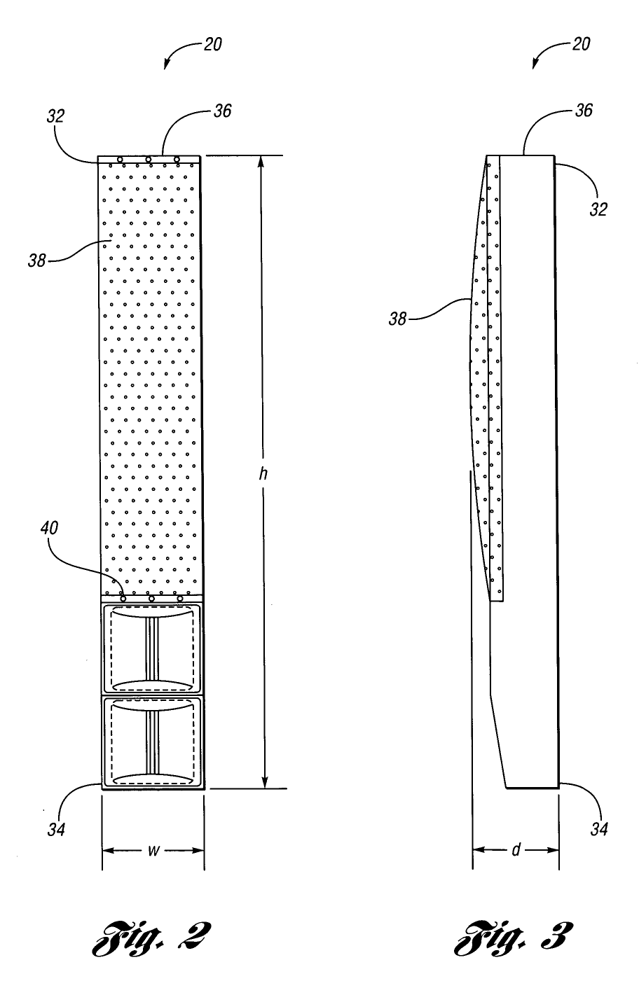

With reference now to FIGS. 2 and 3, the speaker assembly 20 is illustrated enlarged for greater detail. The speaker assembly 20 includes an elongate housing 36 for attachment to the banner brackets 28, 30 and for housing speakers therein. Overall, the speaker assembly 20 has a height (h) (for example 5′-0″ for the embodiment illustrated), a width (w) (for example, 7½″), and a depth (d) (for example, 4¼″).

In order to incorporate the speaker assembly 20 into an aesthetic appearance provided by the structural pole 22 and the banner 26, the speaker assembly 20 is designed for a minimal depth (d). Thus, the speaker assembly 20 is provided generally linear with the width (w) and depth (d) minimized by sizing them to match speakers housed within the elongate housing 36.

For purposes of retrofitting existing banner hardware, the height (h) may be sized to match a corresponding height of the banner 26. The depth (d) which is oriented generally tangential to the structural pole 22, may be sized to match a spacing between opposed faces of banners 26 mounted to the brackets 28, 30. Thus, the depth (d) may be minimized when the height and width are sized to adequately provided a resonating chamber within the elongate housing 36 proportional to speakers provided therein. In order to further blend the speaker assembly 20 within the aesthetic appearance, the depth (d) may be less than or equal to a diameter of the structural pole 22 proximate to the speaker assembly 20, such as within a region of the pole 22 that is oriented between the banner brackets 28, 30.

The invention also contemplates that the width (w) of the speaker assembly 20 may be sized to place the speaker assembly 20 within a gap provided between the structural pole 22 and the banner 26 for retrofitting existing structural poles 22.

The elongate housing 36 may be formed unitarily from a polymeric material. Alternatively, the elongate housing 36 may be formed of a plurality of polymeric panels which are subsequently fastened and adhered together along the seams for resulting in a water tight or weather-proof housing. Alternatively, the housing 36 may be formed from stamped weather-proof sheet metal, such as aluminum or stainless steel, or sheet metal that is coated with a material to make it weather-proof. The interior of the housing 36 may include foam or some other absorbent material for reducing vibrations and providing an adequate resonating chamber for the corresponding speakers.

The speaker assembly 20 includes a screen 38 on the front of the housing 36. The screen 38 is acoustically transparent and shields and protects components within the housing 36. The screen 38 may be formed of any weather-proof acoustically transparent material. The screen 38 illustrated is stamped from stainless steel, such as twelve or fifteen gauge, which is seventy percent perforated for permitting acoustical vibrations to transmit therethrough. The perimeter of the shield may be lined with an elastomeric gasket for sealing the screen 38 to the housing 36. Additionally, a weather-proof foam may be provided on the interior of the screen 38 for preventing elements from passing through the screen, while permitting acoustic vibrations to transmit through the screen 38. The screen 38 may be secured to the housing 36 by a plurality of fasteners 40 about its periphery.

The screen 38 may be formed from any kind of speaker grill that is moisture and weather resistant, that is paintable or accepts a silk-screened material for applying graphics thereto. Further, permanent graphics may be applied to the screen 38 by painting the screen. A banner portion may be affixed to the screen 38 with velcro for adhering it about its periphery. The screen 38 may serve as a banner itself, or may compliment the banner 26 on the structural pole 22.

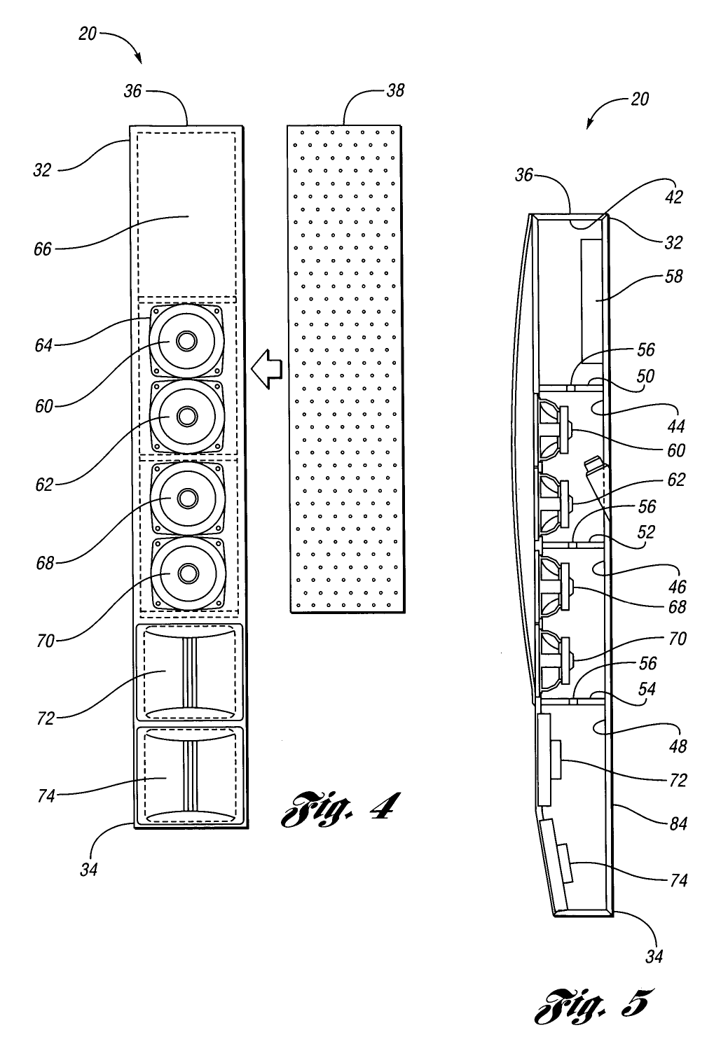

In FIG. 4, the speaker assembly 20 is illustrated with the screen 38 removed for illustrating components within the housing 36. Additionally, FIG. 5 illustrates a fragmented side view for illustration of the components within the housing 36. The elongate housing 36 includes four distinct regions within its internal cavity. Specifically, there is an upper region 42, an upper intermediate region 44, a lower intermediate region 46 and a lower region 48. Each of these regions 42, 44, 46, 48 is divided from one another by a subplate 50, 52, 54 for preventing acoustical vibrations provided by the speaker assembly from resonating throughout the elongate housing 36. Specifically, each of the upper intermediate region 44, lower intermediate region 46 and lower region 48 provide a resonating chamber for the corresponding speakers provided for each region. Each of the subplates 50, 52, 54, includes an aperture 56 formed therethrough for permitting wiring to pass through each region to the corresponding speakers. Each of these apertures 56 may be sealed by a grommet or the like for preventing acoustical vibrations to pass therethrough.

The upper region 42 of the elongate housing 36 houses an amplifier 58 for receiving a power source and a signal and amplifying that signal to the speakers within the speaker assembly 20.

The upper intermediate region 44 includes a pair of woofers 60, 62, which are cone speakers having a flange 64 fastened to a front face 66 of the elongate housing 36. The woofers 60, 62 are low frequency speakers. The rear portion of the woofers 60, 62 extends within the upper intermediate region 44, which acts as a resonating chamber providing back pressure to these speakers.

Likewise, the lower intermediate region 46 also includes a pair of woofers 68, 70. The lower intermediate region 46 serves as a resonating chamber for the woofers 68, 70.

The lower region 48 includes a pair of high frequency drivers 72, 74, and the lower region provides a resonating chamber for the high frequency drivers 72, 74. The high frequency drivers may be cone speakers, tweeters, or the like. The woofers 60, 62, 68, 70 and the high frequency drivers 72, 74 are all stacked linearly, in a direction that is parallel to an axial direction of the structural pole 22, for minimizing the width (w) of the speaker assembly 20.

With reference now to FIG. 6, the lower end 34 of the speaker assembly 20 is illustrated enlarged for detail. The face 66 of the elongate housing 36 includes an aperture 76 formed therein that is sized for receiving the high frequency driver 72. The elongate housing 36 also includes an inset 78 having an aperture 80 formed therethrough for receiving the high frequency driver 74. The inset 78 is canted with respect to the face 66 of the elongate housing 36 for even sound distribution. Specifically, the inset 78 is illustrated with a nine degree offset from the face 66 for orienting the high frequency driver 74 offset from horizontal. The inset 78 may be formed separately from the elongate housing 36, as illustrated in FIG. 6 for affixing the inset 78 to the elongate housing 36 in the manufacturing process.

The linear array of the horizontal facing woofers 60, 62, 68, 70 and high frequency driver 72 in combination with the angled high frequency driver 74 provides uniform sound distribution as experienced by a passerby that is at least six to eight feet from the speaker assembly 20 up to 120 to 140 feet from the speaker assembly 20 in a region that faces the speaker assembly 20.

The invention contemplates utilization of speaker assemblies in accordance with the present invention for smaller ranges of sound distribution than that provided by the speaker assembly 20 of the present invention. For example, the speaker assembly may include an electrostatic speaker. Electrostatic speakers provide sound distribution over a limited range, but only require a housing having a depth of approximately 3½″. A speaker assembly having a housing with a depth of only two inches is adequately thin enough to conceal behind the banner 26, between banners 26, or in other configurations.

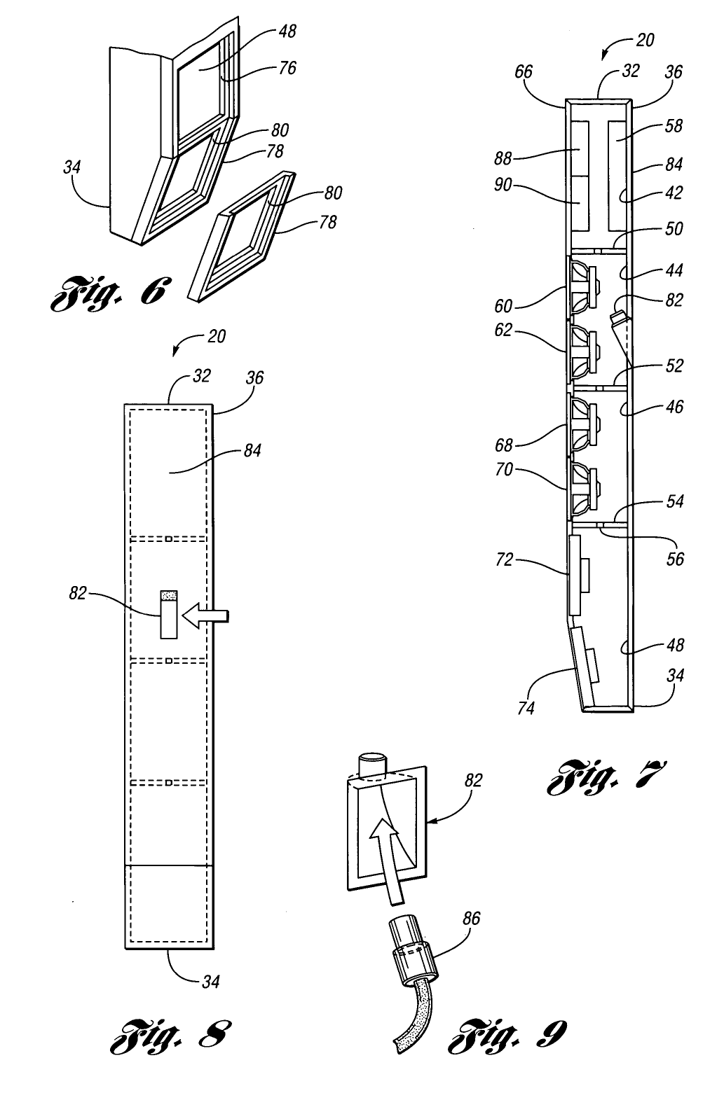

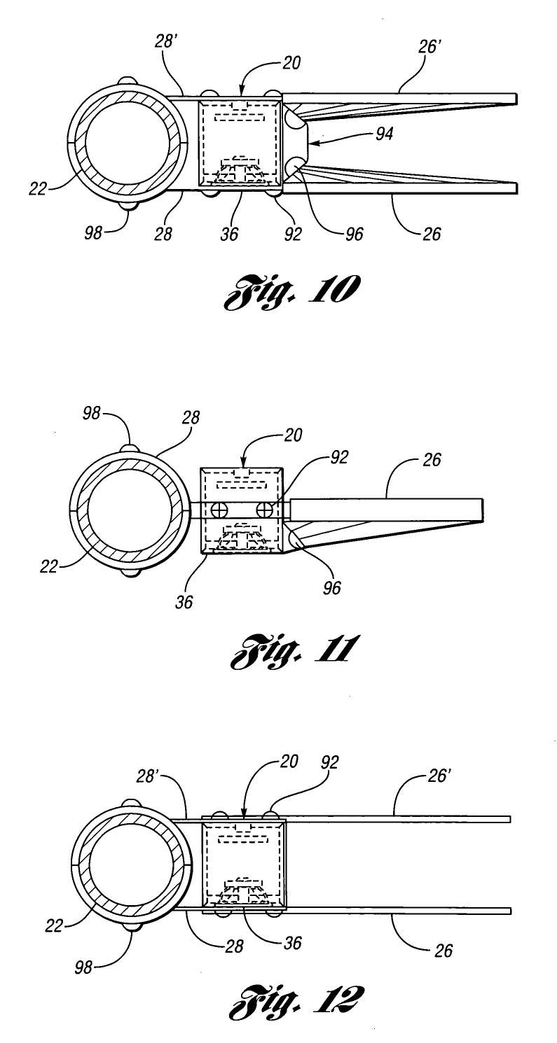

With reference now to FIGS. 7 through 9, the elongate housing 36 includes a port 82 formed within a backplate 84 of the housing 36. The port 82 receives a plug 86 for conveying wiring to the speaker assembly 20. Specifically, wires may be conveyed through the structural pole 22, from an access panel in the structural pole 22, to the port 82 in the speaker assembly 20. The wiring may include a power source, a signal source, or the like.

Alternatively, the speaker assembly 20 may have its own source of power such as a battery 88 located in the upper region 42. Additionally, a solar panel may be provided atop the speaker assembly 20 for converting solar power into power stored in the battery 88.

The speaker assembly 20 may include a driver or processor 90 for providing a signal source to the speakers 60, 62, 68, 70, 72, 74. The processor 90 may include a receiver for receiving a signal source, which is amplified by the amplifier 84 and then transmitted to the speakers 60, 62, 68, 70, 72, 74. Alternatively, the processor 90 may include a series of preprogrammed audio outputs, such as songs, messages or the like and the receiver may receive a signal instructing the processor 90 to play a particular medium.

With reference now to FIG. 10, a top plan view of the speaker assembly 20 is illustrated in cooperation with the structural pole 22. The speaker assembly 20 is mounted to a pair of upper banner brackets 28, 28′ by a plurality of fasteners 92. Although not illustrated in FIG. 10, the speaker assembly 20 is also fastened to a pair of lower banner brackets 30, 30′ by a plurality of fasteners 92. The speaker assembly 20 is placed between the structural pole 22 and a pair of banners 26, 26′ which each face opposed directions.

The banners 26, 26′ may be illuminated by the light source 24. Additionally, a lighting kit 94 may be mounted upon the side of the speaker assembly 20 or to the brackets 28, 28′, 30, 30′. The lighting kit 94 may include a plurality of lights 96 for illuminating the banners 26, 26′ from behind. The lights 96 are adjustable and may also be aimed directly downward for illuminating a pathway below. Additionally, lighting may be provided within the elongate housing 36 for lighting the speaker assembly 20 or the screen 38.

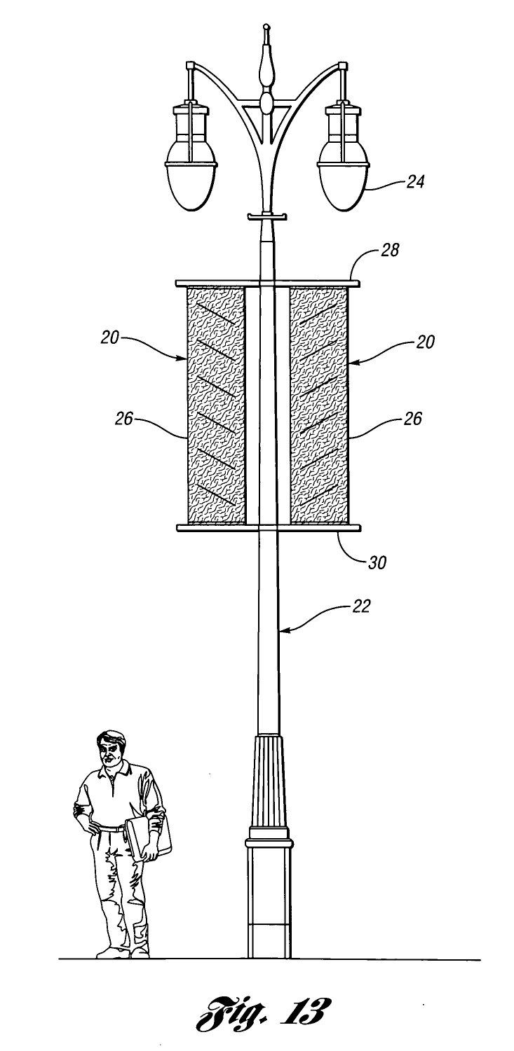

Referring now to FIG. 11, a top plan view of the speaker assembly 20 is illustrated with an alternative mounting configuration for the structural pole 22. The mounting configuration includes a single upper bracket 28 secured to the structural pole 22 by fasteners 98. The speaker assembly 20 is fastened to the upper bracket 28 and a similar lower bracket 30. These brackets 28, 30 include a single banner 26 extending from the upper bracket 28 to the lower bracket 30. Accordingly, the speaker assembly 20 may include adjustable lights 96 for illuminating a front face of the banner 26 or for illuminating the banner 26 from behind.

Referring now to FIG. 12, another alternative mounting configuration is illustrated for the speaker assembly 20. Specifically, the banners 26, 26′ extend sufficiently laterally inward to the structural pole 22 to completely conceal the face 66 and the backplate 84 of the speaker assembly 20. Thus, when a pedestrian faces either banner 26, 26′, the speaker assembly 20 cannot be viewed and therefore does not detract from the ornamental or aesthetic appearance provided by the structural pole 22 and the banners 26, 26′.

FIG. 13 illustrates another alternative mounting configuration for the speaker assembly 20 in accordance with the present invention. Specifically, the banners 26 are each disposed over a speaker assembly 20 and the banners 26 are each sized to completely conceal the speaker assembly 20. By providing banners 26 on both lateral sides of the structural pole 22, the speaker assemblies 20 may face opposed directions for providing sound distribution from opposed directions of the structural pole 22.

In summary, a speaker assembly is provided that may be incorporated into an aesthetic or ornamental environment without detracting from or disturbing the appearance.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A speaker assembly for attachment to a structural pole, the speaker assembly comprising:
an elongate housing having an upper end adapted to be affixed to an upper banner bracket of a structural pole, and a lower end adapted to be affixed to a lower banner bracket of the structural pole, and the housing being sized to retain at least one speaker therein wherein the housing provides an aesthetic appearance corresponding to a banner attached to a structural pole; and
at least one speaker retained within the housing and oriented to face generally outward from the housing for transmitting acoustic vibrations to a corresponding environment.

2. The speaker assembly of claim 1 wherein the housing further comprises a height sized to match a height of a banner of the structural pole, and a depth oriented generally tangential of the pole, the depth being sized to match a spacing between opposed faces of the banner.

3. The speaker assembly of claim 1 wherein the housing further comprises a height oriented in an axial direction of the structural pole, a width oriented in a direction that the banner brackets extend from the structural pole, and a depth oriented generally perpendicular to the height and the width, wherein the height and width of the housing are each greater than the housing depth.

4. The speaker assembly of claim 1 wherein the housing further comprises a height oriented in an axial direction of the structural pole, a width oriented in a direction that the banner brackets extend from the structural pole, and a depth oriented generally perpendicular to the height and the width, wherein the depth is less than or equal to a diameter of a region of the structural pole oriented between the banner brackets.

5. The speaker assembly of claim 1 wherein the housing further comprises a width oriented in a direction that the banner brackets extend from the structural pole, and the width is sized to orient the speaker assembly disposed between the structural pole and a banner on the banner brackets.

6. The speaker assembly of claim 1 wherein the at least one speaker further comprises a plurality of speakers.

7. The speaker assembly of claim 1 wherein the at least one speaker further comprises a cone speaker.

8. The speaker assembly of claim 1 wherein the speaker assembly is adapted to receive a banner mounted thereto for aesthetically concealing the speaker assembly.

9. The speaker assembly of claim 1 further comprising a light source for illuminating a banner mounted to the banner brackets.

10. The speaker assembly of claim 1 further comprising a light source for illuminating a region of a corresponding thoroughfare.

11. The speaker assembly of claim 1 wherein the speaker assembly is wired into the structural pole for receiving a power source.

12. The speaker assembly of claim 1 wherein further comprising a receiver mounted within one of the structural pole and the speaker assembly housing for receiving a wireless signal.

13. The speaker assembly of claim 1 wherein the at least one speaker further comprises a linear array of speakers.

14. The speaker assembly of claim 13 wherein the linear array of speakers are oriented in an axial direction of the structural pole.

15. The speaker assembly of claim 13 wherein at least one speaker of the linear array of speakers is oriented facing a direction that is angularly offset from a tangential direction relative to the structural pole for directing acoustical vibrations to a targeted region in a corresponding thoroughfare.

16. The speaker assembly of claim 13 wherein at least one speaker of the linear array of speakers is oriented facing a direction that is angularly offset from a horizontal direction for even sound distribution to a corresponding thoroughfare.

17. A speaker assembly for attachment to a structural pole, the speaker assembly comprising:
an upper bracket adapted to be affixed to a structural pole;
a lower bracket adapted to be affixed to the structural pole spaced apart from the upper bracket along the pole;
an elongate housing having an upper end adapted to be affixed to the upper banner bracket, and a lower end adapted to be affixed to the lower banner bracket, and the housing being sized to retain at least one speaker therein; and
at least one speaker retained within the housing, and oriented to face generally outward from the housing for transmitting acoustic vibrations to a corresponding environment;
wherein the speaker assembly provides an aesthetic appearance corresponding to a banner attached to a structural pole.

18. A method for mounting a speaker assembly to a structural pole, the method comprising:
providing a speaker assembly having an elongate housing with a speaker therein; and
mounting the speaker assembly to banner brackets on a structural pole.

19. The method of claim 18 further comprising mounting a banner to the banner brackets.

20. The method of claim 18 further comprising orienting the speaker assembly between the structural pole and a banner on the banner brackets.
